(19) United States
(12) Patent Application Publication
(10) Pub. No.: US 2002/0116672 A1
(43) Pub. Date: Aug. 22, 2002

(54) Pattern data transmission device and pattern data transmission method

(75) Inventor: Masatoshi Kanzaki, Kawasaki-shi (JP)

Correspondence Address: DARBY & DARBY P.C., 805 Third Avenue, New York, NY, 10022, US

(73) Assignee: ANDO ELECTRIC CO., LTD.

(21) Appl. No.: 10/076,710

(22) Filed: Feb. 14, 2002

(30) Foreign Application Priority Data
Feb. 19, 2001 (JP) P2001-042300

(51) Int. Cl. G11C 29/00

(52) U.S. Cl. 714/718

(57) ABSTRACT

In order to realize high-speed and highly efficient pattern data transmission without enlarging the size of circuits, a pattern data transmission device is provided which transmits compressed pattern data for generating a test pattern to be used for the inspection of a semiconductor integrated circuit from an external storage device to a pattern memory of a pattern generating device comprises a decompression section which determines whether decompressed pattern data is the same as decompressed pattern data previously written in a pattern memory according to compressed pattern data when writing the decompressed pattern data inside the compressed pattern data into a pattern memory, and an automatic disposition section which reads out the same decompressed pattern data on the pattern memory according to memory control information inputted from the decompression section and makes a copy of the same decompressed pattern data on the pattern memory.

### BACKGROUND OF THE INVENTION

1. Field of the Invention

This invention relates to a pattern data transmission device and a pattern data transmission method which transmit data (pattern data) for generating test patterns for input into a semiconductor integrated circuit for the purpose of testing a memory of the pattern generating device.

2. Description of Related Art

As is commonly known, a semiconductor integrated circuits inspection device tests the operation characteristics of various semiconductor integrated circuit. This semiconductor integrated circuit inspection device inputs the test pattern (input-signal for inspection) respectively to the terminals of the semiconductor integrated circuit mounted on a test board, and examines whether or not the operation of the semiconductor integrated circuit is correct, by evaluating the timing and the level of the output pattern which is output respectively from terminals according to the test pattern.

This kind of semiconductor integrated circuit inspection device comprises, for example, an inspection device unit and a control unit such as an engineering work station for controlling the inspection device unit. This kind of semiconductor integrated circuit inspection device generates test patterns necessary for the examination of the semiconductor integrated circuit by the pattern generating device provided in the inspection device unit. The pattern generating device is provided with a memory for storing the pattern data corresponding to various test patterns, and the pattern data transmitted from the controlling unit is stored in this memory. In the control unit, an external storage device such as a hard-disk device is provided for storing and retaining the pattern data in a state in which the data is compressed.

Recently, according to the high level of integration of semiconductor integrated circuits and the increasing number of terminals, the data size of the above pattern data is reaching nearly the Gigabyte scale. In order to transmit and store such large volumes of pattern data efficiently from the controlling unit to the memory of the pattern generating device, highly efficient compression and decompression devices are necessary. For compressing and decompressing, conventionally the pattern data in a compressed condition was decompressed by a tester controlling program, such a huge volume of decompressed pattern data was transmitted to the memory of the pattern generating device through a tester bus, and the pattern data under a compressed condition was decompressed by an special decompressing circuit and transmitted to the memory.

However, in the case of decompression by a program, highly efficient pattern data transmission is impossible because of limitations such as the time for handling the decompression by tester controlling program and the transmission capacity of the tester bus. On the other hand, in the case in which a special decompression circuit is used, the circuit becomes large; thus, the reduction in size and reduction in cost of the semiconductor integrated circuit inspection device are hindered. Also, the compression rate of an algorithm may often inevitably be low due to the size of the circuit and to the trade-off with the compression efficiency.

### SUMMARY OF THE INVENTION

This invention was made in consideration of the above problems, and an object of the present invention is to realize high speed, highly efficient, pattern data transmission without increasing the size of the circuit to a great extent.

In order to achieve the object, in the first aspect of the pattern data transmission device of the present invention, a pattern data transmission device which transmits compressed pattern data for generating a test pattern to be used for the inspection of a semiconductor integrated circuit from an external storage device to a pattern memory of a pattern generating device comprises a decompression section which determines whether decompressed pattern data is the same as decompressed pattern data previously written in a pattern memory according to compressed pattern data when writing the decompressed pattern data in the compressed pattern data into a pattern memory, and an automatic disposition section which reads out the same decompressed pattern data in the pattern memory according to memory control information inputted from the decompression section and makes a copy of the same decompressed pattern data in the pattern memory.

In the second aspect of the pattern data transmission device of the present invention, compressed pattern data is compressed and encoded according to an LZ77 (Lempel-Ziv 77) method, the decompression section which determines whether uncompressed pattern data is the same as uncompressed pattern data previously written in a pattern memory according to a control bit of the compressed code, and outputs the memory control information to the automatic disposition section regarding reading out the same decompressed pattern data from the pattern memory and making the copy in the pattern memory by referring to a table index and a repetition number included in the compressed code.

In the third aspect of the present invention, the compressed pattern data is compressed and encoded according to LZW (Lempel Ziv Welch) method, the decompression section registers number-reference data, to an index table for decompression in turn, made of absolute address and repetition number of the same decompressed pattern data previously written in the pattern memory every time the decompressed pattern data forming the compressed code is read, and outputs the memory control information to the automatic disposition section regarding reading out the same decompressed pattern data from the pattern memory and making a copy in the pattern memory by referring to the index table for decompression.

The first aspect of the pattern data transmission method of the present invention for transmitting the compressed pattern data for generating a test pattern supplied for the inspection of a semiconductor integrated circuit from the external storage device to the pattern memory of the pattern generating device is that, when the decompressed pattern data in the compressed pattern data is written in the pattern memory, in the case of decompressed pattern data which is the same as the decompressed pattern data previously written in a pattern memory, the same decompressed pattern data in the pattern memory is copied.

The second aspect of the pattern data transmission method of the present invention is that the compressed pattern data is compressed and encoded according to the LZ77 method, in the case in which the same decompressed pattern data is written in the pattern memory previously according to the control bit of the compressed code, by referring to the table index and repetition number included in the compressed code, the memory control information for reading out the same decompressed pattern data from the pattern memory and for making the copy in the pattern memory as required, the same uncompressed pattern data is copied in the pattern memory according to the memory control information.

The third aspect of the pattern data transmission method of the present invention is that the compressed pattern data is compressed and encoded according to an LZW method, the decompression section registers number-reference data, to an index table for decompression in turn, made of absolute address and repetition number of the same decompressed pattern data previously written in the pattern memory every time the decompressed pattern data forming the compressed code is read, and acquires the memory control information regarding reading out the same decompressed pattern data from the pattern memory and making the copy in the pattern memory by referring to the index table for decompression, and makes a copy of same decompressed pattern data in the pattern memory according to the memory control information.

As explained above, according to present invention, a pattern data transmission device which transmits compressed pattern data for generating a test pattern to be used for the inspection of a semiconductor integrated circuit from an external storage device to a pattern memory of a pattern generating device comprises a decompression section which determines whether decompressed pattern data is the same as decompressed pattern data previously written in a pattern memory according to compressed pattern data when writing the decompressed pattern data in the compressed pattern data into a pattern memory, and an automatic disposition section which reads out the same decompressed pattern data on the pattern memory according to memory control information inputted from the decompression section and makes a copy of the same decompressed pattern data on the pattern memory; thus, it is possible for the compressed pattern data to be decompressed in the pattern memory and transmitted at high speed without enlarging the circuit.

Also by adopting the LZW method as the compression code method of the pattern data, a higher compression rate of the pattern data than in the case of the LZ77 method can be realized; thus, the use capacity of the compressed pattern data in the external storage device to which the compressed pattern data is transmitted can be reduced.

### BRIEF DESCRIPTION OF THE DRAWINGS

FIG. 1 is a block diagram of the pattern data transmission device of the first embodiment of the present invention.

FIG. 2 is a block diagram of the pattern data transmission device of the second embodiment of the present invention.

### DETAILED DESCRIPTION OF THE INVENTION

A preferred embodiment of the pattern data transmission device and the pattern data transmission method of the present invention are explained with reference to the drawings.

First Embodiment

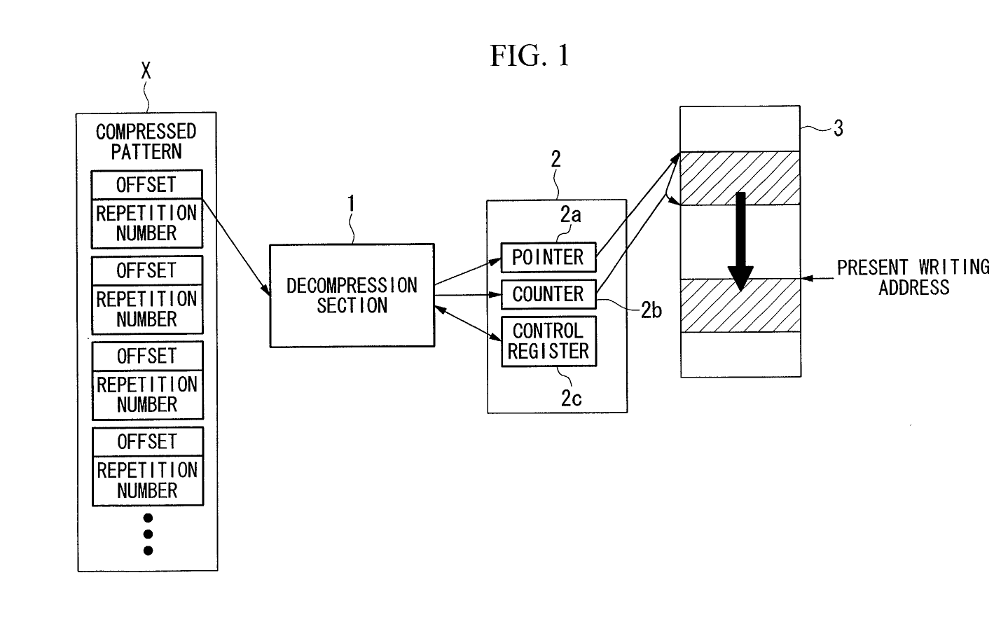

FIG. 1 is a block diagram of the pattern data transmission device of the first embodiment of the present invention. In FIG. 1, reference symbol X indicates a compressed pattern data. Reference symbol 1 indicates a decompression section, and reference numeral 2 is an automatic disposition section, reference numeral 3 indicates a pattern memory. Here, the decompression section 1 and the automatic disposition section 2 are provided in the inspection device unit as hardware.

Compressed pattern data X is a pattern data which has been compressed, and is the object to be transmitted in the present embodiment. This compressed pattern data X is made such that the pattern data is compressed and encoded using the “LZ77 method” as an algorithm for the compression. The test pattern supplied for the examination of the semiconductor integrated circuits very often ahs the same pattern in a repeated manner; thus, the pattern data may be compressed using various algorithms for compression, and the pattern data is stored as a compressed pattern data X in an external storage device (ordinarily, a hard-disk device) provided as an auxiliary device of the control unit.

The above “LZ77 method” is a modified method of an LZ code (compression code) proposed by A. Lempel and J. Ziv. Such a compression code have two kinds of data format according to the value of the top bit (control bit) of the bit stream. That is, in the case in which control bit is “0” (zero), the bit row showing “table index” (12 bit fixed) and the bit row showing “repetition number” (variable length) are disposed following after the control bit “0” (zero). On the other hand, in the case in which the control bit is “1” (one), the bit row showing “decompressed pattern data” (12 bit fixed) is disposed following after the control bit “1” (one).

That is, the above compressed pattern X includes the relative address of the same pattern row which appears previously following after the random compressed pattern data (pattern row) as the table index, and the code length of the pattern row. Also, the above compressed pattern X includes the repetition number of the appearance of the pattern row as the above repetition time.

The decompression section 1 reads such a compressed pattern X, and controls the automatic disposition section 2. Automatic disposition section 2 comprises a pointer 2a, a counter 2b, and a control register 2c. The absolute address of the pattern memory 3 is written in the pointer 2a. The above repetition number is written in the counter 2b. Various control information is written in the control register 2c from the above decompression section 1 respectively. Additionally, each data to be stored in the above pointer 2a, counter 2b, and control register 2c is memory control information in the present embodiment.

Next, the operation of the pattern data transmission device which is constructed in such a way is explained in detail.

First, the writing-start-address is instructed by the control program as a present-writing-address. Then, each data stream of compressed pattern X is sent out to the decompression section 1 in turn by the above control program.

The decompression section 1 reads each bit stream of the compressed pattern X from the beginning to the end in turn, writes the above decompressed pattern data as it is into the pattern memory 3 in turn, and increments the present-writing-address in turn. In this series of transmission and decompression processes, the decompression section 1 controls the automatic disposition section 2 according to “offset (relative address)” and “repetition number” following after the control bit when the control bit “0 (zero)” is detected.

That is, the decompression section 1 writes the address after the above offset is deducted from the present-writing-address of the pattern memory 3 when the control bit “0 (zero)” is detected by the pointer 2a, and the decompression section 1 writes the repetition number onto the counter 2b. Then, by writing the starting-instruction into the control register 2c, the decompression section 1 makes a copy and renews the present-writing-address.

Automatic disposition section 2 reads the same pattern row as is stored previously in the above relative address according to the instruction of the control register 2c if data is set in each register in this way. The automatic disposition section 2 makes a copy of the pattern row successively as many times as the repetition number is set in the counter 2b from the top address such as the present-writing-address. For example, if the repetition number is set as “2”, the automatic disposition section 2 writes the same pattern row stored previously in the address made after above relative address which is set in the pointer 2a is deducted from the present-writing-address as a top address of the present-writing-address.

According to the present embodiment, every time the control bit “0” is detected by the decompression section “1”, the same pattern row as is stored previously in the pattern memory 3 is copied and is stored differently from the way in which the same pattern row (a part of compressed pattern X) is read from the external storage device of the control unit. That is, the decompression section 1 and the automatic disposition section 2 as relatively simple hardware structure are provided, and the same pattern row as is previously stored in the pattern memory 3 is copied, differently from the way in which copy is made from the external storage device of the control unit or the buffer memory of the decompression section 1. Thus, high-speed, highly efficient pattern data transmission can be realized without enlarging the circuit.

Second Embodiment

Next, the second embodiment of the present invention is explained. The second embodiment relates to the transmission of the compressed pattern X′ to which the “LZW” method is applied as a compression code method. The same reference numerals are applied to the same structures as in the first embodiment, and explanation thereof is omitted.

Here, the compressed pattern X′ does not include the “repetition number” as the compressed information following after the control bit “0 (zero)”, and has only an index of table (index table 1a for decompressing) made in the decompression section 1A; thus, the compression rate of compressed pattern X in the LZW method is higher than the compression rate of the compressed pattern X.

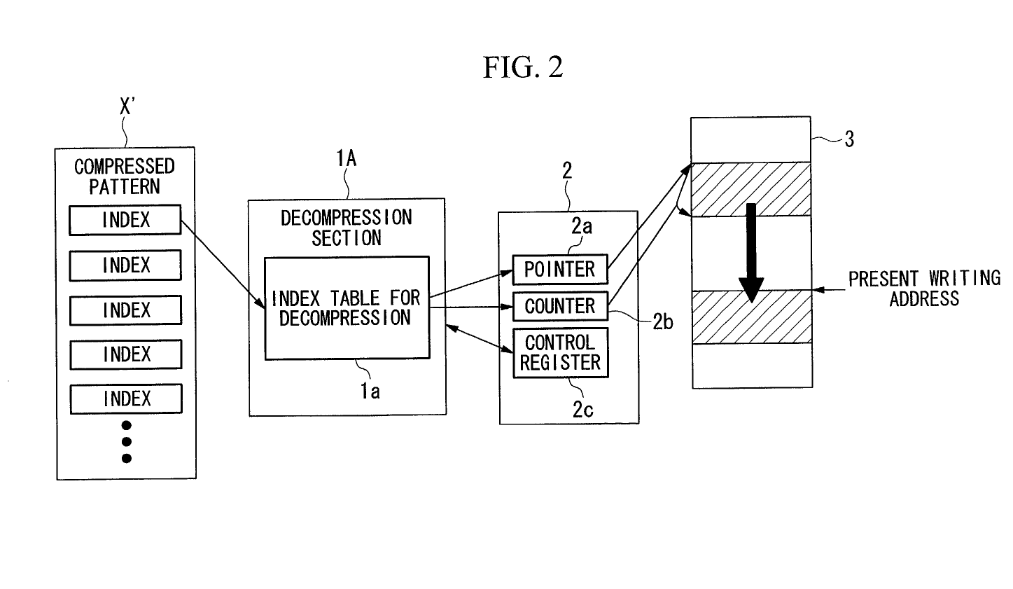

In the present embodiment, as shown in FIG. 2, an index table 1a for decompression is provided in the decompression section 1A. This index table la for decompression compensates for the “repetition number” in the above LZ77 method, and the index table 1a for decompression is made by registering a plurality of the absolute addresses of the pattern rows written in the pattern memory 3 previously and the repetition number as the number-reference data. Such reference data is registered in the index table 1a for decompression in turn for the purpose of updating each time the decompression section 1A reads the bit stream forming the compressed pattern X′ successively.

That is, the decompression section 1A registers the number-reference data into the index table 1a for decompression in turn every time each bit stream forming the compressed pattern X′ is read in turn, and the pattern row which is read as a part of the bit stream sets the absolute address obtained from the index table 1a for decompression on the pointer 2a, and sets the repetition number on the counter 2b by successively referring to the absolute address and the repetition number of the same pattern row previously registered in the index table 1a for decompression.

Automatic disposition section 2 reads the same pattern row which is previously stored in the absolute address set in the pointer 2a when the data is set in each register in this way, and copies the same pattern row in the present-writing-address as many times as the repetition number is set in the counter 2b.

According to the present embodiment, similarly to the above first embodiment, the decompression section 1A and the automatic disposition section 2 are provided as relatively simple hardware, and the same pattern row previously stored in the pattern memory 3 is copied differently from the way in which the same pattern row is read from the external storage device of the control unit; thus, high-speed, highly efficient transmission of pattern data can be realized without enlarging the circuit. Also, according to the present embodiment, a higher compression rate of the compressed pattern X′ (LZW method) than that of the compressed pattern X (LZ77 method) of the first embodiment can be used; thus, the memory capacity of the external storage device can be reduced.

As explained above, the test pattern which is supplied for the testing of the semiconductor integrated circuit often appears in the same repeated manner. In order to compress the pattern data for generating such a test pattern, the method is effective in which the pattern data which appeared is stored in the dictionary in turn, and after the second time or later, the index of this dictionary is stored in the pattern memory 3. Ordinarily, in such a decompression device for an algorithm, the device must have a storage device for dictionary so as be able to restore while revising the dictionary.

However, it is difficult to have a plurality of such decompression devices in one semiconductor integrated circuit inspection device because it increases the size of the circuit, which increases cost and takes up space. If only one decompression device is provided in the semiconductor integrated circuit inspection device, and if the ratio between the transmission capacity of the path between the decompression device and the pattern memory and the transmission capacity of the path between the external storage device in which the compressed pattern is stored and the decompression device is smaller than the compression ratio, efficient pattern transmission cannot be realized because the pattern data which is decompressed from the middle of the path is transmitted. Generally, as far as the transmission capacity is concerned, the path between above external storage device and the decompression device does not differ greatly from the path between the decompression device and the pattern memory; thus, having only one compression decompression device is not very effective from a transmission efficiency point of view.

What is claimed is:

1. A pattern data transmission device, which transmits compressed pattern data for generating a test pattern used for the inspection of a semiconductor integrated circuit from an external storage device to a pattern memory of a pattern generating device, comprising:
a decompression section which determines whether decompressed pattern data is the same as decompressed pattern data previously written in a pattern memory according to compressed pattern data when writing the decompressed pattern data in the compressed pattern data into a pattern memory; and
an automatic disposition section which reads out the same decompressed pattern data on the pattern memory according to memory control information inputted from the decompression section and makes a copy of the same decompressed pattern data on the pattern memory.

2. A pattern data transmission device according to claim 1, wherein
the compressed pattern data is compressed and encoded according to an LZ77 method; and the decompression section which determines whether decompressed pattern data which is the same as decompressed pattern data previously written in a pattern memory according to a control bit of the compressed code, outputs the memory control information to the automatic disposition section for reading out the same uncompressed pattern data from the pattern memory making the copy in the pattern memory by referring to a table index and a repetition number included in the compressed code.

3. A pattern data transmission device according to claim 1, wherein;
the compressed pattern data is compressed and encoded according to LZW method; and
the decompression section registers number-reference data, to an index table for decompression in turn, comprising absolute address and repetition number of the same decompressed pattern data previously written in the pattern memory every time the decompressed pattern data forming the compressed code is read, and outputs the memory control information to the automatic disposition section for reading out the same decompressed pattern data from the pattern memory and making the copy in the pattern memory by referring to the index table for decompression.

4. A pattern data transmission method for transmitting the compressed pattern data for generating a test pattern supplied for the inspection of a semiconductor integrated circuit from the external storage device to the pattern memory of the pattern generating device, wherein when the decompressed pattern data inside the compressed pattern data is written in the pattern memory, and when the decompressed pattern data is the same as the decompressed pattern data previously written in a pattern memory, the same decompressed pattern data in the pattern memory is copied.

5. A pattern data transmission method according to claim 4, wherein:
the compressed pattern data is compressed and encoded according to an LZ77 method;
memory control information for reading out the same decompressed pattern data from the pattern memory and for making a copy in the pattern memory is acquired when the same uncompressed pattern data is written in the pattern memory previously according to the control bit of the compressed code, by referring to a table index and a repetition number included in the compressed code,
the same decompressed pattern data is copied in the pattern memory according to the memory control information.

6. A pattern data transmission method according to claim 4, wherein:
the compressed pattern data is compressed and encoded according to an LZW method; and the decompression section registers number-reference data, to an index table for decompression in turn, comprising absolute address and a repetition number of the same decompressed pattern data previously written in the pattern memory every time the decompressed pattern data forming the compressed code is read, and acquires the memory control information for reading out the same decompressed pattern data from the pattern memory and making a copy in the pattern memory by referring to the index table for decompression, and makes a copy of the same decompressed pattern data in the pattern memory according to the memory control information.
